(19) United States
(12) Patent Application Publication
(10) Pub. No.: US 2024/0274416 A1
(43) Pub. Date: Aug. 15, 2024

(54) PLASMA PROCESS SIMULATION METHOD AND SEMICONDUCTOR DEVICE MANUFACTURING METHOD INCLUDING THE SAME

(71) Applicant: SAMSUNG ELECTRONICS CO., LTD., Suwon-si (KR)

(72) Inventors: Jaesik An, Suwon-si (KR); Dongig Oh, Suwon-si (KR); Thanh Cuong Nguyen, Suwon-si (KR); Suntaek Lim, Suwon-si (KR); Seungmin Lee, Suwon-si (KR); Inkook Jang, Suwon-si (KR); Joohyun Jeon, Suwon-si (KR)

(21) Appl. No.: 18/430,475

(22) Filed: Feb. 1, 2024

(30) Foreign Application Priority Data
Feb. 13, 2023 (KR) 10-2023-0018980
May 25, 2023 (KR) 10-2023-0067727

(51) Int. Cl. H01J 37/32; H01J 37/34

(52) U.S. Cl. CPC H01J 37/32926; H01J 37/3476; H01J 2237/24585; H01J 2237/332

(57) ABSTRACT

Provided is a plasma process simulation method including defining a plasma reaction for a wafer, calculating a reaction parameter of the plasma reaction, and generating a plasma process simulation profile based on a calculated reaction parameter. The reaction parameter are set based on a physical reaction and a chemical reaction.

### CROSS-REFERENCE TO RELATED APPLICATIONS

This application is based on and claims priority under 35 U.S.C. § 119 to Korean Patent Application Nos. 10-2023-0018980, filed on Feb. 13, 2023, and 10-2023-0067727, filed on May 25, 2023, in the Korean Intellectual Property Office, the disclosures of which are incorporated by reference herein in their entirety.

### TECHNICAL FIELD

This document relates to a plasma process simulation method and a semiconductor device manufacturing method including the same, and more particularly, to a plasma process simulation method for improving reliability of a plasma process and a semiconductor device manufacturing method including the same.

### BACKGROUND

As an example of processes of manufacturing a semiconductor device, there is a plasma process including plasma-induced deposition, plasma etching, and plasma cleaning. As semiconductor devices are miniaturized and highly integrated, the influence of minute errors in a plasma process on the quality of semiconductor products increases. Therefore, various techniques for precisely simulating a plasma process are being proposed.

### SUMMARY

The present disclosure provides a plasma process simulation method including physical and chemical reactions and a semiconductor device manufacturing method including the same.

In general, innovative aspects of the subject matter described in this specification can be embodied in a plasma process simulation method including: defining a plasma reaction for a wafer, calculating a reaction parameter of the plasma reaction, and generating a plasma process simulation profile based on the calculated reaction parameter, wherein the reaction parameter are set based on a physical reaction and a chemical reaction.

Another general aspect can be embodied in a plasma process simulation method including defining a plasma reaction for a wafer, calculating a reaction parameter of the plasma reaction, generating a calculated simulation profile of a plasma process based on a calculated reaction parameter, and generating a final simulation profile based on the calculated simulation profile, wherein reaction parameter is set based on a physical sputtering reaction and a chemical adsorption reaction.

Another general aspect can be embodied in a method of manufacturing a semiconductor device, the method including preparing a wafer, defining a plasma reaction for the wafer, calculating a reaction parameter of the plasma reaction, generating a calculated simulation profile of a plasma process based on a calculated reaction parameter, generating a final simulation profile based on the calculated simulation profile, performing a plasma treatment for the wafer based on the final simulation profile, and performing subsequent semiconductor processes on the wafer, wherein the reaction parameter has information regarding materials constituting the wafer, information regarding plasma, and a temperature of the wafer as variables.

Another general aspect can be embodied in a system including at least one processor, and a non-transitory storage medium for storing instructions that, when executed by the at least one processor, instruct the at least one processor to perform operations for a plasma process simulation for a wafer, wherein the operations include defining a plasma reaction for the wafer, calculating a reaction parameter of the plasma reaction, and generating a plasma process simulation profile based on a calculated reaction parameter, and the reaction parameter are set based on a physical reaction and a chemical reaction.

Another general aspect can be embodied in a non-transitory storage medium for storing instructions that, when executed by the at least one processor, instruct the at least one processor to perform operations for a plasma process simulation for a wafer, wherein the operations include defining a plasma reaction for the wafer, calculating a reaction parameter of the plasma reaction, and generating a plasma process simulation profile based on a calculated reaction parameter, and the reaction parameter are set based on a physical reaction and a chemical reaction.

### BRIEF DESCRIPTION OF THE DRAWINGS

FIG. 1 is a diagram of an example of a plasma processing apparatus.

FIG. 2 is a flowchart of an example of a plasma process simulation method.

FIG. 3 is a flowchart of an example of a method of generating a final simulation profile.

FIG. 4 is a flowchart of an example of a method of calculating a reaction parameter.

FIG. 5 is a flowchart of an example of a method of calculating a physical sputtering parameter.

FIG. 6 is a flowchart of an example of a method of calculating a sputtering yield.

FIG. 7 is a schematic view of an example of a process in which plasma ions are incident on a wafer.

FIG. 8 is a flowchart of an example of a method of calculating a chemical adsorption parameter.

FIG. 9 is a graph showing adsorption thicknesses according to etching depths at different temperatures.

FIG. 10 is a flowchart of an example of a method of manufacturing a semiconductor device, the method including a plasma process simulation.

FIG. 11 is a block diagram showing an example of a computing system.

### DETAILED DESCRIPTION

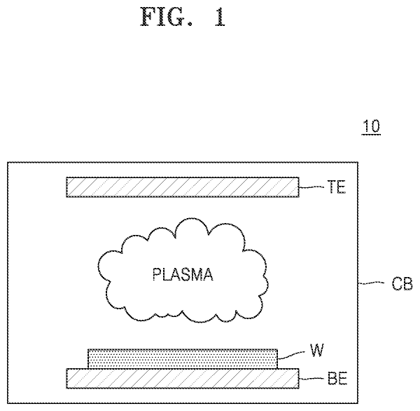

FIG. 1 is a diagram for describing a plasma processing apparatus.

Referring to FIG. 1, a plasma processing apparatus 10 may include a chamber CB, a bottom electrode BE, and a top electrode TE. The plasma processing apparatus 10 may be configured to generate plasma. Although FIG. 1 shows an example in which the plasma processing apparatus 10 includes a capacitively coupled plasma source, the present disclosure is not limited thereto. For example, the plasma processing apparatus 10 may include an inductively coupled plasma source, a microwave plasma source, a remote plasma source, etc.

Hereinafter, for convenience of explanation, an example in which a wafer W to be processed is disposed in the chamber CB and the plasma processing apparatus 10 is a wafer processing apparatus for processing the wafer W will be mainly described.

The plasma processing apparatus 10 may perform one of plasma annealing, plasma etching, plasma enhanced chemical vapor deposition, sputtering, and plasma cleaning on the wafer W.

In some implementations, the plasma processing apparatus 10 may perform, for example, a reactive ion etching process. Reactive ion etching is a dry etching process in which species (radicals, ions, etc.) excited by a high frequency RF power source etch the wafer W or a thin film in a low-pressure chamber. Reactive ion etching may be performed through a bombardment of energetic ions and physical/chemical complex actions of chemically active species. Reactive ion etching may include etching of an insulation layer like a silicon oxide layer, etching of a metallic material layer, and etching of a doped or undoped semiconductor material layer.

In some implementations, the plasma processing apparatus 10 may perform, for example, an isotropic etching process on the wafer W. The plasma processing apparatus 10 may perform a process of substituting silicon oxide formed on the wafer W with ammonium hexafluorosilicate ((NH₄)₂SiF₆) and removing the ammonium hexafluorosilicate through annealing.

In some implementations, the plasma processing apparatus 10 may perform a process of isotropically removing any one of crystalline, amorphous silicon, silicon nitride, and/or a metal on the wafer W by alternately and repeatedly performing plasma treatment and annealing treatment on the any one of the crystalline and/or amorphous silicon, the silicon nitride, and the metal.

The chamber CB is a chamber for a plasma process, and plasma may be generated therein. The chamber CB may confine a reaction space in which plasma is formed, thereby sealing the reaction space from the outside. The chamber CB generally includes a metal material and may maintain a grounded state to block noise from the outside during a plasma process. Although not shown, a gas inlet, a gas outlet, a view-port, etc. may be formed in the chamber CB. A process gas needed for a plasma process may be supplied through the gas inlet. Here, the process gas may refer to all gases needed in a plasma process, e.g., a source gas, a reaction gas, and a purge gas. After the plasma process, gases inside the chamber CB may be exhausted to the outside through the gas outlet. Also, the pressure inside the chamber CB may be adjusted through the gas outlet. In addition, the inside of the chamber CB may be monitored through the view-port.

The top electrode TE may be disposed in an upper region of the chamber CB, the bottom electrode BE may be disposed in a lower region of the chamber CB, and the wafer W may be disposed on the bottom electrode BE. Although not shown, a capacitor, ground, and/or radio frequency (RF) power may be electrically connected to the top electrode TE and the bottom electrode BE. In some implementations, the bottom electrode BE may include an electrostatic chuck ESC that fixes and supports the wafer W by using electrostatic force. Also, the chamber CB may include a gas supply unit (not shown) and a gas discharge unit (not shown), wherein the gas supply unit may supply a reaction gas into the chamber CB, and a gas may be exhausted through the gas discharge unit to maintain the chamber CB in a vacuum state.

The wafer W may include, for example, silicon (Si). The wafer W may include a semiconductor element like germanium (Ge) or a compound semiconductor like silicon carbide (SiC), gallium arsenide (GaAs), indium arsenide (InAs), and indium phosphide (InP). Also, the wafer W may include dielectric materials like silicon dioxide (SiO₂) and silicon nitride (Si₃N₄), a low-k material like SiOCN and amorphous carbon, a high-k material like hydrofluoro-olefin (HFO) and zirconium dioxide (ZrO), and/or a metal material like aluminum (Al), copper (Cu), tungsten (W), titanium nitride (TiN), and aluminum nitride (AlN), and/or a polymer material like CₓF_{y} and ammonium hexafluorosilicate ((NH₄)₂SiF₆).

In some implementations, the wafer W may have a silicon-on-insulator (SOI) structure. The wafer W may include a buried oxide layer. In some implementations, the wafer W may include a conductive region, e.g., a well doped with impurities. In some implementations, the wafer W may have various device isolation structures like a shallow trench isolation (STI), separating doped wells from one another.

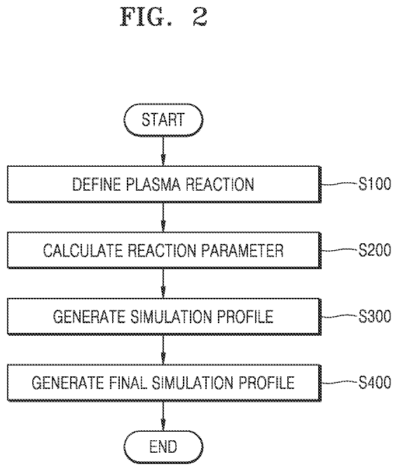

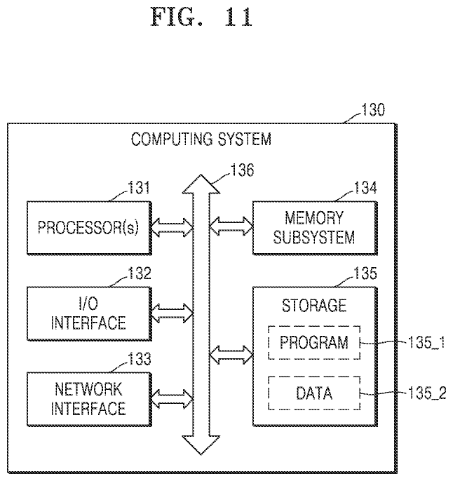

FIG. 2 is a flowchart of an example of a plasma process simulation method. The plasma process simulation method may be performed in any computing system (e.g., 130 of FIG. 11). Hereinafter, descriptions will mainly focus on a plasma etching process simulation, but techniques may be applied not only to a plasma etching process, but also to any processes like a plasma annealing process and/or a plasma cleaning process.

The various operations of methods described below may be performed by any suitable means capable of performing the operations, e.g., various hardware and/or software component(s), circuits, and/or module(s). Software may include an ordered list of executable instructions to implement logical functions and may be implemented by any processor readable medium used by or associated with an instruction executing system apparatus or device (e.g., a single or multi-core processor, a system including a processor, etc.).

Operations, blocks, or functions of a method or an algorithm described below may be directly implemented in hardware, a software module executed by a processor, or a combination thereof. When implemented in software, functions may be stored as one or more instructions or code on a tangible non-transitory computer-readable medium. A software module may exist on random access memory (RAM), flash memory, read-only memory (ROM), electrically programmable ROM (EPROM), electrically erasable programmable ROM (EEPROM), registers, a hard disk, a removable disk, a CD-ROM, or any other type of storage medium.

Referring to FIGS. 1 and 2, first, a plasma reaction for the wafer W may be defined (operation S100). The plasma reaction may include a physical reaction (e.g., a physical plasma reaction) and/or a chemical reaction (e.g., a chemical plasma reaction) occurring at the wafer W. For example, the plasma reaction may include physical sputtering and/or chemical adsorption.

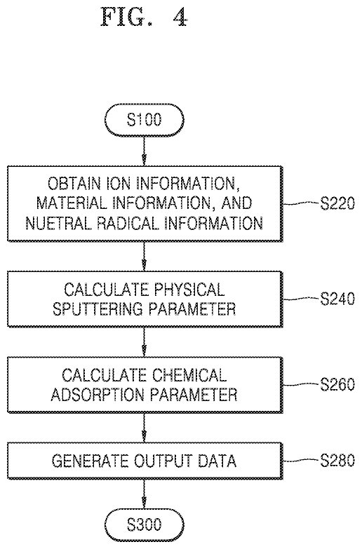

Thereafter, a reaction parameter may be calculated (operation S200). The reaction parameter may be defined by a physical plasma reaction and/or a chemical plasma reaction occurring at the wafer W. For example, the reaction parameter may be defined by a physical plasma reaction and/or a chemical plasma reaction occurring on a surface of the wafer W. The reaction parameters may be expressed as a function for the wafer W, plasma ions, and a temperature. For example, the reaction parameter may include the average atomic mass of materials constituting the wafer W, the average atomic number of the materials constituting the wafer W, the average atomic mass of plasma ions, the average atomic number of plasma ions, and the temperature of the bottom electrode BE as variables. An example of a process of calculating the reaction parameter is described below in detail with reference to FIGS. 4 to 9.

Thereafter, based on a calculated reaction parameter, a plasma process simulation profile may be generated (operation S300). The plasma process simulation profile may include plasma process result information. As will be described later, the plasma process simulation profile may be expressed as a function regarding the energy of plasma ions, the average atomic mass of the plasma ions, the average atomic mass of the wafer W, the temperature of the wafer W, the temperature of the bottom electrode BE, and/or the angle of incidence (0) of the plasma ions. In other words, the plasma process simulation profile may have the energy of plasma ions, the average atomic mass of the plasma ions, the average atomic mass of the wafer W, the temperature of the wafer W, the temperature of the bottom electrode BE, and/or the angle of incidence (0) of the plasma ions as variables. For example, the plasma process simulation profiles may include information regarding etching degrees according to depths. In contrast to an experimental simulation profile described later, a simulation profile obtained in operation S300 may be referred to as a calculated simulation profile.

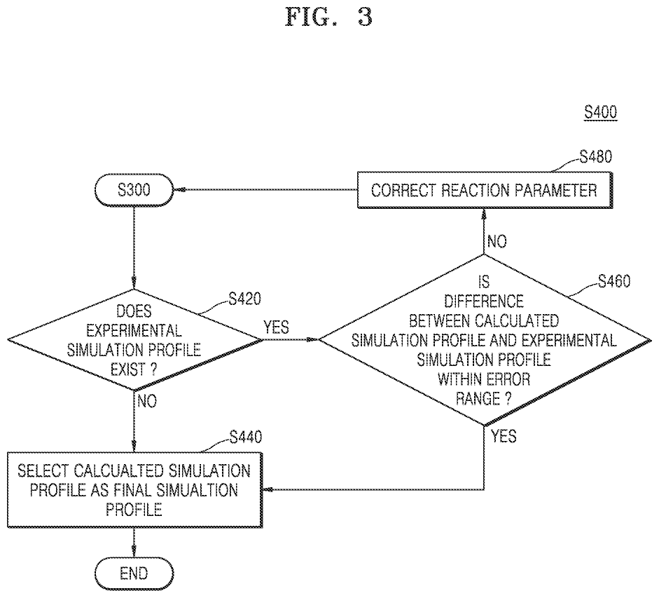

FIG. 3 is a flowchart of an example of a method of generating a final simulation profile, Description of FIG. 3 will be given below with reference to FIGS. 1 and 2 together.

Referring to FIG. 3, after a calculated simulation profile is generated in operation S300, a final simulation profile may be set (operation S400). To set the final simulation profile, a process of determining whether an experimental simulation profile corresponding to the same conditions exists may be performed (operation S420). The same condition may refer to a case where the variables of the plasma process simulation profile, that is, the energy of plasma ions, the average atomic mass of the plasma ions, the average atomic mass of the wafer W, the temperature of the wafer W, the temperature of the bottom electrode BE, and/or the angle of incidence (0) of the plasma ions, are the same.

When no experimental simulation profile corresponding to the same conditions exists, a simulation profile set in operation S300 may be set as the final simulation profile (operation S440). Conversely, when an experimental simulation profile corresponding to the same conditions exists, the experimental simulation profile may be compared with the calculated simulation profile generated in operation S300 (operation S460). Here, the experimental simulation profile may refer to a profile of a plasma process obtained through an experiment.

Thereafter, the scheme for calculating the reaction parameters of operation S200 is corrected (operation S480), and the method may proceed to operation S300 of generating the plasma process simulation profile or operation S440 of setting the calculated simulation profile as the final simulation profile. For example, when the difference between the calculated simulation profile and the experimental simulation profile is within an error range, the calculated simulation profile may be set as the final simulation profile (operation S440). Conversely, when the difference between the experimental simulation profile and the calculated simulation profile is outside the error range, the reaction parameter may be corrected (operation S480) and a simulation profile may be re-generated. Operation S480 of correcting the reaction parameters may be performed by adding some limiting conditions to calculation of the reaction parameters.

FIG. 4 is a flowchart of an example of a method of calculating a reaction parameter, Description of FIG. 4 will be given below with reference to FIGS. 1 and 2 together.

Referring to FIG. 4, in a method of calculating a reaction parameter, ion information, material information, and neutral radical information may be obtained (operation S220). In a computing system, ion information, material information, and neutral radical information may be obtained in any manner. For example, ion information, material information, and neutral radical information stored in a storage may be loaded into a memory of the computing system, ion information, material information, and neutral radical information may be received by the computing system through a network, and ion information, material information, and neutral radical information may be input to the computing system through an input device.

The ion information is information regarding particles incident on the wafer W and may include information regarding plasma ions participating in a plasma process. For example, the ion information may include average atomic mass information, average atomic number information, energy, and angles of incidence of plasma ions. For example, plasma ions may include halogen ions (e.g., F⁺, CI⁺, Br⁺, and I⁺), noble gas ions (e.g., He⁺, Ne⁺, Ar⁺, Kr⁺, and Xe⁺), and inert gas ions (e.g., He⁺, Ne⁺, Ar⁺, Kr⁺, Xe⁺), and/or molecular ions (CF⁺, CF₂⁺, CF₃⁺, and HF⁺). In contrast to neutral radicals described later, plasma ions may be electrically positive and/or negative. In other words, plasma ions may have a charge and may not be electrically neutral. As such, plasma ions may be expressed as, for example, DₘEₙ, where Dₘ denotes D-type atoms with m concentration, and Eₙ denotes E-type atoms with n concentration. The average atomic mass M₁ and the average atomic number Z₁ of the plasma ions may be expressed as in Equation 1 below.

$${M}_{1} = ( m {M}_{D} + n {M}_{E} ) / ( m + n ) {Z}_{1} = ( m {Z}_{D} + n {Z}_{E} ) / ( m + n ) \qquad [ Equation 1 ]$$

Here, M₁ denotes the average atomic mass of plasma ions, Z₁ denotes the average atomic number of plasma ions, M_{D} denotes the atomic mass of a D atom, M_{E} denotes the atomic mass of an E atom, Z_{D} denotes the atomic number of the D atom (i.e., the number of protons), Z_{E} denotes the atomic number of the E atom (i.e., the number of protons), m denotes the number D-type atoms, and n denotes the number of E-type atoms.

Equation 1 shows an example in which plasma ions include two different elements D and E, but the number of elements that the plasma ions may include is not limited thereto. For example, plasma ions may include only one element or three or more elements.

The material information is information regarding materials constituting the wafer W and may include information regarding materials of the wafer W participating in the plasma process. For example, the material information may include average atomic mass information and average atomic number information regarding materials constituting the wafer W. For example, as described above, the wafer W may include a dielectric material (e.g., SiO₂, Si₃N₄), a low-k material (SiOCN), amorphous carbon, a high-k material (e.g., HfO, ZrO, etc.), a semiconductor material (e.g., Si, SiGe, GaN, etc.), a metal material (e.g., Al, Cu, W, TIN, AlN, etc.), and/or a polymer material (e.g., CₓF_{y}, (NH₄)₂SiF₆, etc.). In this regard, a material constituting the wafer W may be expressed as, for example, AᵢBⱼCₖ. Similarly to above, Aᵢ denotes A-type atoms of i concentration, Bⱼ denotes B-type atoms of j concentration, and Cₖ denotes C-type atoms of k concentration. The average atomic mass M₂ and the average atomic number Z₂ of the wafer W may be expressed as in Equation 2 below.

$${M}_{2} = ( i {M}_{A} + j {M}_{B} + k {M}_{C} ) / ( i + j + k ) {Z}_{2} = ( i {Z}_{A} + j {Z}_{B} + k {Z}_{C} ) / ( i + j + k ) \qquad [ Equation 2 ]$$

Here, M₂ denotes the average atomic mass of the wafer W, Z₂ denotes the average atomic number of the wafer W, MA denotes the atomic mass of an A atom, MB denotes the atomic mass of a B atom, Mc denotes the atomic mass of a C atom, Z_{A} denotes the atomic number (i.e., number of protons) of the A atom, Z_{B} denotes the atomic number (i.e., number of protons) of the B atom, and Z_{C} denotes the atomic number (i.e., the number of protons) of the C atom.

Equation 2 shows an example in which the material constituting the wafer W includes three different elements A, B, and C, but the number of elements that the material constituting the wafer W may include is not limited thereto. For example, the material constituting the wafer W may include two or fewer elements or four or more elements.

The neutral radical information is information regarding electrically neutral particles and may include information regarding neutral atoms or molecules participating in the plasma process. As will be discussed later, neutral radicals may participate in a chemical adsorption process. For example, neutral radicals may include halogen radicals (F, Cl, Br, and I) that are single atom radicals and/or molecular radicals (CF, CF₂, and CF₃).

Thereafter, a physical sputtering parameter may be calculated (operation S240). The physical sputtering parameters may include, for example, threshold energy (Eₜₕ), a maximum plasma ion incidence angle (θₘₐₓ), and/or a sputtering yield (θₘₐₓ and θ=0°). Physical sputtering refers to a process in which plasma or high-energy particles are incident on a target material and, due to collisions with the plasma or high-energy particles, atoms or ions are emitted from the target material. Particles emitted from the target material may be deposited on a nearby substrate (e.g., a wafer W) to form a thin-film.

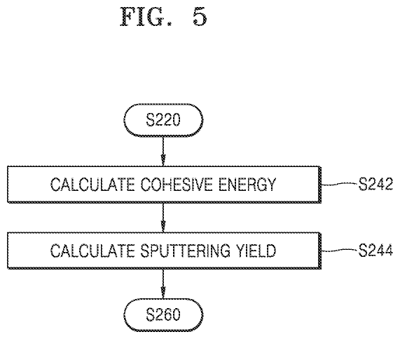

FIG. 5 is a flowchart of an example of a method of calculating a physical sputtering parameter.

Referring to FIG. 5, to calculate a physical sputtering parameter, first, cohesive energy may be calculated (operation S242). The cohesive energy may be calculated based on the chemical formula of the material constituting the wafer W. Cohesive energy refers to the amount of energy needed to completely separate a group of atoms or molecules that are bonded to one another. In other words, cohesive energy may indicate the strength of the bonding force between atoms or molecules. Therefore, cohesive energy may indicate the strength of chemical bonds between atoms or molecules of a material, and the stronger the chemical bonds are, the higher the cohesive energy may be. The cohesive energy of the material constituting the wafer W may be calculated by Equation 3 below.

$${E}_{c o h} = ( i {E}_{isloated - atom A} + j {E}_{i s loated - atom B} + k {E}_{isloated - atom C} - {E}_{bulk} ) / ( i + j + k ) \qquad [ Equation 3 ]$$

Here, E_{coh} denotes cohesive energy, E_{isolated-atom A} denotes energy when only atom A exists independently, E_{isolated-atom B} denotes energy when only atom B exists independently, E_{isolated-atom C} denotes energy when only atom C exists independently, and E_{bulk} denotes energy of the material constituting the wafer W, e.g., the material AᵢBⱼCₖ.

Here, the energy of the material constituting the wafer W and the energy of a single atom may be calculated by using the Hartree-Fock method, the semi-empirical quantum chemistry method, the Møller-Plesset perturbation method, the coupled cluster method, the quantum Monte-Carlo method, etc. In some implementations, the energy of the material constituting the wafer W and the energy of a single atom may be calculated by using the Thomas-Fermi model method, the orbital-free density functional theory method, the linearized augmented plane-wave method, and/or the projected augmented wave method. In some implementations, the cohesive energy may be obtained through an experiment.

Thereafter, the sputtering yield may be calculated (operation S244). The sputtering yield may be calculated based on the cohesive energy. The sputtering yield refers to the amount of a material released from or removed from the material (e.g., the wafer W) in a sputtering process. In the sputtering process, the material may be referred to as a target material. The sputtering yield may vary depending on the energy of particles incident on the target material, the mass of the particles, the angle of incidence of the particles, the composition of the target material, the structure of the target material, the temperature of the target material, etc.

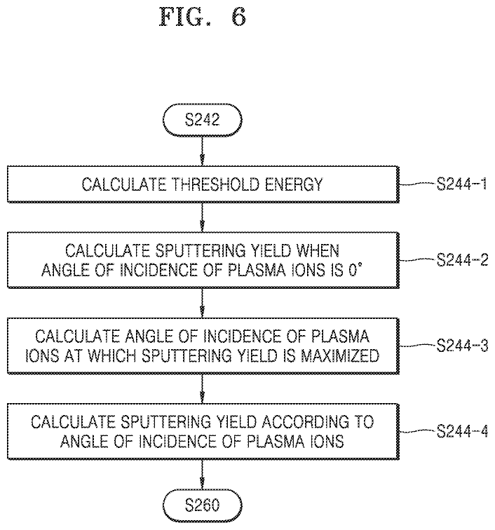

FIG. 6 is a flowchart of an example of a method of calculating a sputtering yield.

Referring to FIG. 6, to calculate the sputtering yield, first, threshold energy may be calculated (operation S244-1). The threshold energy may be calculated based on the cohesive energy, the average atomic mass of plasma ions, and the average atomic mass of the wafer W. The threshold energy may be defined as the minimum energy for removing target material atoms from the surface of the wafer W when plasma ions have the minimum incident energy. The threshold energy may be calculated by Equation 4 below.

$${E}_{th} = \{ \begin{matrix}6.7 \frac{{E}_{coh}}{γ} , & {M}_{1} > {M}_{2} \\ ( 1 + 5.7 \frac{{M}_{1}}{{M}_{2}} ) \frac{{E}_{coh}}{γ} , & {M}_{1} \leq {M}_{2}\end{matrix} \qquad [ Equation 4 ]$$

$$γ = \frac{4 {M}_{1} {M}_{2}}{{( {M}_{1} + {M}_{2} )}^{2}}$$

Here, Eₜₕ denotes the threshold energy, E_{coh} denotes the cohesive energy, M₁ denotes the average atomic mass of plasma ions, and M₂ denotes the average atomic mass of the wafer W.

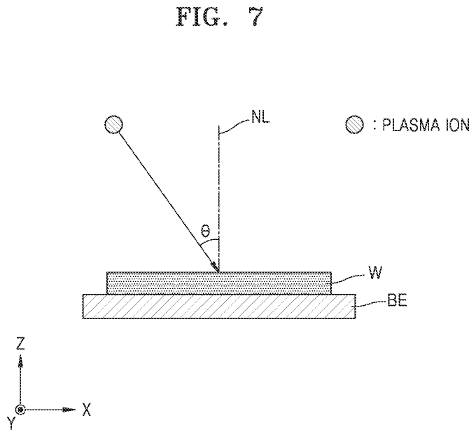

FIG. 7 is a schematic view of an example of a process in which plasma ions are incident on a wafer. Descriptions thereof will be given with reference to FIG. 6 together.

Referring to FIG. 7, the angle of incidence (θ) of plasma ions may refer to an angle at which plasma ions collide with the wafer W. The angle of incidence (θ) of the plasma ions may refer to an angle between a normal line NL, which corresponds to a direction perpendicular to the surface of the wafer W, and the plasma ions. FIG. 6 shows an example in which the main surface of the wafer W is disposed parallel to the horizontal direction (X direction and/or Y direction) and the normal line NL is formed in the vertical direction (Z direction). For example, when the bottom electrode BE is inclined, the normal line NL is misaligned with the vertical direction (Z direction), and thus, the angle of incidence (θ) of the plasma ions may be changed.

In the present specification, the horizontal direction (X direction and/or Y direction) represents a direction parallel to the main surface of the wafer W, and the vertical direction (Z direction) represents a direction perpendicular to the horizontal direction (X direction and/or Y direction).

After operation S244-1, the sputtering yield when the angle of incidence (θ) of the plasma ions is 0° may be calculated (operation S244-2). The sputtering yield may refer to the average number of atoms removed from the surface of the wafer W when the angle of incidence (θ) of the plasma ions is 0°. As will be described later, when the angle of incidence (θ) of the plasma ions is 0°, the plasma ions may be perpendicularly incident on the surface of the wafer W. The sputtering yield when the angle of incidence (θ) of plasma ions is 0° may be calculated by Equation 5 below.

$$Y ( E , θ = 0 ) = 0.042 \frac{α ( {M}_{2} / {M}_{1} )}{{E}_{c o h}} {\frac{{S}_{n} ( E )}{1 + Γ {k}_{e} {ϵ}^{0.3}} [ 1 - {( \frac{{E}_{th}}{E} )}^{0.5} ]}^{2.5} \qquad [ Equation 5 ]$$

$$α = \{ \begin{matrix}0.0875 {( {M}_{2} / {M}_{1} )}^{- 0.15} + 0.165 ( {M}_{2} / {M}_{1} ) , & {M}_{1} > {M}_{2} \\ 0.249 {( {M}_{2} / {M}_{1} )}^{0.56} + 0.0035 {( {M}_{2} / {M}_{1} )}^{1.5} , & {M}_{1} \leq {M}_{2}\end{matrix} Γ = \frac{0.35 {E}_{c o h}}{1 + {( {M}_{1} / 7 )}^{3}}$$

$$ϵ ( E ) = \frac{0.03255}{{Z}_{1} {{Z}_{2} ( {Z}_{1}^{2 / 3} + {Z}_{2}^{2 / 3} )}^{0.5}} \frac{{M}_{2}}{{M}_{1} + {M}_{2}} E {s}_{n}^{TP} ( ϵ ) = \frac{3.441 {ϵ}^{0.5} ln ( ϵ + 2.718 )}{1 + 6.355 {ϵ}^{0.5} + ϵ ( 6.882 {ϵ}^{0.5} - 1.708 )}$$

$${k}_{e} = 0.079 \frac{{( {M}_{1} + {M}_{2} )}^{3 / 2}}{{M}_{1}^{3 / 2} + {M}_{2}^{1 / 2}} \frac{{Z}_{1}^{2 / 3} {Z}_{2}^{1 / 2}}{{( {Z}_{1}^{2 / 3} + {Z}_{2}^{2 / 3} )}^{3 / 4}} {S}_{n} ( E ) = \frac{84.78 {Z}_{1} {Z}_{2}}{{( {Z}_{1}^{2 / 3} + {Z}_{2}^{2 / 3} )}^{1 / 2}} \frac{{M}_{1}}{{M}_{1} + {M}_{2}} {s}_{n}^{TP} ( ϵ )$$

Here, θ denotes the angle of incidence of the plasma ion, Y denotes the sputtering yield, E denotes the incident plasma ion energy, Eₜₕ denotes the threshold energy, E_{coh} denotes the cohesive energy, M₁ denotes the average atomic mass of the plasma ions, M₂ denotes the average atomic mass of the wafer W, Z₁ denotes the average atomic number of plasma ions, and Z₂ denotes the average atomic number of the wafer W.

Thereafter, the angle of incidence (θ) of the plasma ions corresponding to the maximum sputtering yield, which is θₘₐₓ, may be calculated (operation S244-3). θₘₐₓ may be calculated by Equation 6 below.

$${θ}_{max} = \frac{π}{2} - 286 {ψ}^{0.45} ψ = {n}^{0.5} {a}^{3 / 2} \frac{{( {Z}_{1} {Z}_{2} )}^{0.5}}{{( {Z}_{1}^{2 / 3} + {Z}_{2}^{2 / 3} )}^{0.25}} {( E )}^{- 0.5} a = 0.4685 {( \frac{1}{{Z}_{1}^{2 / 3} + {Z}_{2}^{2 / 3}} )}^{0.5} \qquad [ Equation 6 ]$$

Here, θₘₐₓ denotes the angle of incidence corresponding to the maximum sputtering yield, E denotes the incident plasma ion energy, Z₁ denotes the average atomic number of the plasma ions, Z₂ denotes the average atomic number of the wafer W, and n denotes the number density of the wafer W.

Thereafter, the sputtering yield according to the angle of incidence θ of the plasma ions may be calculated (operation S244-4). The sputtering yield may represent the average number of atoms removed from the surface of the wafer W, according to the angle of incidence θ of the plasma ions. The sputtering yield according to the angle of incidence θ of the plasma ions may be calculated by Equation 7 below.

$$Y ( E , θ ) = Y ( E , 0 ) [ {cos ( θ )}^{- f} exp \{ f cos ( {θ}_{max} ) [ 1 - \frac{1}{cos ( θ )} ] \} \qquad [ Equation 7 ]$$

$$f = ( 1 + 2.5 \frac{1 - ζ}{ζ} ) {f}_{s} \qquad {f}_{s} = ( 0.94 - 0.00133 \frac{{M}_{2}}{{M}_{1}} ) {E}_{c o h}^{0.5} \qquad ζ = 1 - {( \frac{{E}_{th}}{E} )}^{0.5}$$

Here, θ denotes the angle of incidence of the plasma ions, Y denotes the sputtering yield, Eₜₕ denotes the threshold energy, E denotes the incident plasma ion energy, E_{coh} denotes the cohesion energy, M₁ denotes the average atomic mass of the plasma ions, and M₂ denotes the average atomic mass of the wafer W.

The maximum value of the sputtering yield may be calculated by substituting θ of Equation 7 with θₘₐₓ of Equation 6.

Returning back to FIG. 4, a chemical adsorption parameter may be calculated (operation S260). The chemical adsorption parameter may include adsorption energy and a sticking coefficient. The chemical adsorption refers to a process in which atoms or molecules are bonded to the surface of a solid material through chemical bonds.

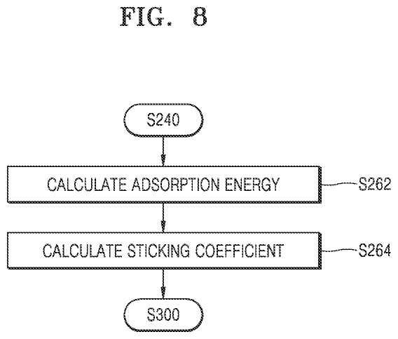

FIG. 8 is a flowchart of an example of a method of calculating a chemical adsorption parameter.

Referring to FIG. 8, to calculate a chemical adsorption parameter, adsorption energy may be calculated (operation S262). The adsorption energy may refer to energy needed by atoms or molecules to be adsorbed (or bonded) to a surface. In other words, the adsorption energy may be a measure of the interaction strength between an absorbate and a surface. For example, when the interaction between an adsorbate and a surface is strong, it may indicate that the absorbate has high adsorption energy. The adsorption energy may be calculated by Equation 8 below.

$${E}_{b} = E ( gas ) + E ( target substrate ) - E ( substrate - gas ) \qquad [ Equation 8 ]$$

Here, E_{b} denotes the adsorption energy, E(gas) denotes the energy of a neutral radical gas, E(target substrate) denotes the energy of a target substrate (e.g., the wafer W), and E(substrate-gas) denotes the energy of a substrate (e.g., the wafer W)-gas system.

Thereafter, the sticking coefficient may be calculated (operation S264). The sticking coefficient may be calculated based on the adsorption energy. The sticking coefficient may refer to a probability that particles colliding with a surface are not reflected and are stuck to the surface. For example, the sticking coefficient may refer to a ratio between the number of particles adhering to a surface and the number of particles colliding with the surface. For example, the sticking coefficient may vary depending on a surface temperature and particle-surface interaction characteristics. For example, when the sticking coefficient increases, the probability that particles colliding with the surface stick to the surface may increase.

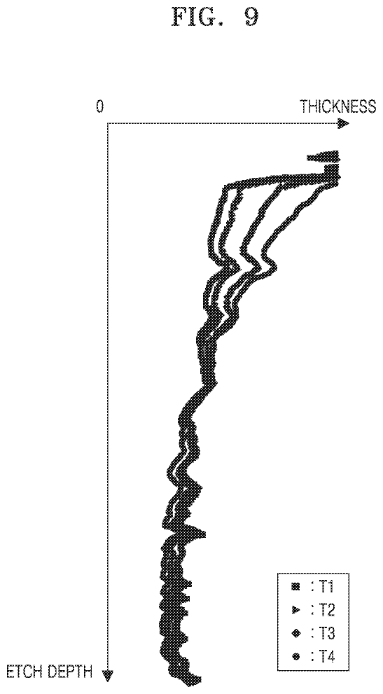

FIG. 9 is a graph showing adsorption thicknesses according to etching depths at different temperatures. In the graph, the horizontal axis represents the adsorption thickness, and the vertical axis represents the etching depth. The horizontal axis and the vertical axis are indicated by arbitrary units (a.u.). A point where the etching depth is 0 represents the top surface of the wafer W, and, as the etching depth increases, it indicates that a distance becomes closer to the bottom electrode BE. In FIG. 9, the temperature refers to the temperature of the surface (e.g., the top surface) of the wafer W. The top surface of the wafer W may refer to a surface farthest from the bottom electrode BE.

Referring to FIG. 9, when the temperature of the surface of the wafer W varies, the adsorption thickness according to an etching depth may vary. FIG. 9 shows adsorption thicknesses according to etching depths when the temperature of the surface of the wafer W is first to fourth temperatures T1, T2, T3, and T4, respectively.

The adsorption thicknesses according to etching depths may be one of the plasma process simulation profiles of FIG. 2. The adsorption thickness may be correlated with the sticking coefficient of FIG. 8. Therefore, the temperature of the surface of the wafer W may be a variable of the sticking coefficient. In other words, the temperature of the surface of the wafer W may be a variable of a simulation profile.

Returning back to FIG. 8, the sticking coefficient may be calculated by Equation 9 below.

$$SC ( T ) = \frac{{P}_{trap}}{1 + exp ( - \frac{{E}_{b}}{{k}_{B} T} )} {P}_{trap} = {\int }_{0}^{{E}_{b}} 2 {( \frac{E}{π} )}^{\frac{1}{2}} {( \frac{1}{{k}_{B} T} )}^{\frac{3}{2}} exp ( - \frac{E}{{k}_{B} T} ) d E \qquad [ Equation 9 ]$$

Here, T denotes the temperature of the surface of the target substrate (e.g., the wafer W), SC(T) denotes the sticking coefficient according to the temperature, E_{b} denotes the adsorption energy, Pₜᵣₐₚ denotes the Maxwell-Boltzmann distribution of the adsorption energy, and kg denotes the Boltzmann constant.

The temperature of the bottom electrode BE serving as a stage may be lower than that of the wafer W. When the temperature of the stage is equal to and/or higher than the temperature of the wafer W, excessive heat may be transmitted to the wafer W and the wafer W may be damaged. The temperature of the stage and the temperature of the wafer W may have a relationship of Equation 10 below.

$${T}_{E S C} = {T}_{s u b} - 80.5 ° C . \qquad [ Equation 10 ]$$

Here, T_{ESC} denotes the temperature of the stage (e.g., an electrostatic chuck), and T_{sub} denotes the temperature of the wafer W.

Returning back to FIG. 4, output data may be generated based on the physical sputtering parameter and the chemical adsorption parameter (operation S280). The output data may include information regarding the threshold energy, the sputtering yield, a maximum angle, and/or the sticking coefficient. Therefore, the output data may be used for plasma process simulation. Therefore, the reliability and the yield of the plasma process may be improved.

In typical plasma process simulations, reaction parameters are randomly selected without mathematical and/or physical calculations. Therefore, the reliability of the reaction parameters is relatively low, and thus the reliability of the plasma simulation process is relatively low. Also, a simulation profile is experimentally obtained in an attempt to compensate the low reliability of the plasma simulation process.

A plasma process simulation according to implementations of the present disclosure includes mathematical and/or physical calculation of reaction parameters. For example, the reaction parameter according to implementations of the present disclosure may be calculated in consideration of a physical sputtering process and a chemical adsorption process. Therefore, the reliability of the reaction parameter increases, and thus, the reliability of the plasma simulation process may be improved. Also, as the reliability of the plasma simulation process is improved, an experimental simulation profile does not have to be used.

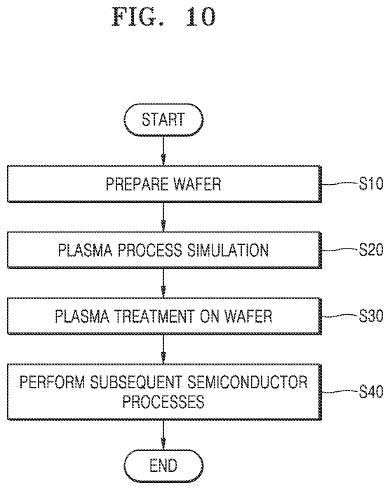

FIG. 10 is a flowchart of a an example of a method of manufacturing a semiconductor device, the method including a plasma process simulation. Descriptions thereof will be given below with reference to FIGS. 1 to 9 together.

Referring to FIG. 10, the wafer W may be prepared inside the chamber CB (operation S10). For example, the wafer W may be disposed on the bottom electrode BE of the chamber CB. The bottom electrode BE may be a stage supporting the wafer W. For example, the bottom electrode BE may be an electrostatic chuck.

Thereafter, a plasma process simulation for the wafer W may be performed (operation S20). For example, a plasma process may include any plasma processes, such as a plasma etching process, a plasma annealing process, and/or a plasma cleaning process.

The plasma process simulation of operation S20 may be substantially the same as the plasma process simulation process of FIG. 2. In other words, the plasma process simulation process of operation S20 may include defining a plasma reaction (operation S100), calculating a reaction parameter (operation S200), generating a plasma process simulation profile (operation S300), and generating a final simulation profile (operation S400).

Thereafter, based on the plasma process simulation, a plasma treatment may be performed on the wafer W (operation S30). The plasma treatment may include processes, such as etching, deposition, and cleaning for the wafer W using plasma.

After the plasma treatment for the wafer W, subsequent semiconductor processes are performed on the wafer W (operation S40). Subsequent semiconductor processes for the wafer W may include various processes. For example, the subsequent semiconductor processes may include a deposition process, an etching process, an ion process, a cleaning process, etc. Plasma may or may not be used in the subsequent semiconductor processes. Also, the subsequent semiconductor processes may include a singulation process of individualizing the wafer W into individual semiconductor chips, a test process of testing the semiconductor chips, and a packaging process of packaging the semiconductor chips. A semiconductor device may be formed through the subsequent semiconductor processes for the wafer W.

FIG. 11 is a block diagram showing an example of a computing system. In some implementations, the plasma process simulation method described above with reference to FIGS. 1 to 10 may be performed on a computing system 130 of FIG. 11.

Referring to FIG. 11, the computing system 130 may be a stationary computing system, such as a desktop computer, a workstation, or a server, or a portable computing system, such as a laptop computer. As shown in FIG. 11, the computing system 130 may include at least one processor 131, an input/output interface 132, a network interface 133, a memory subsystem 134, and a storage 135, and the at least one the processor 131, the input/output interface 132, the network interface 133, the memory subsystem 134, and the storage 135 may communicate with one another through a bus 136.

The at least one processor 131 may also be referred to as a processing unit and, for example, may include at least one of a micro-processor, an application processor (AP), a digital signal processor (DSP), a graphics processing unit (GPU), etc., capable of executing an arbitrary instruction set (e.g., Intel Architecture-32 (IA-32), 64-bit extended IA-32, x86-64, PowerPC, Sparc, MIPS, ARM, IA-64, etc.). For example, the at least one processor 131 may access the memory subsystem 134 via the bus 136 and execute instructions stored in the memory subsystem 134.

The input/output interface 132 may include or provide access to an input device, such as a keyboard and a pointing device, and/or an output device, such as a display device and a printer. A user may trigger execution of a program 135_1 and/or loading of data 135_2 through the input/output interface 132, may input ion information, material information, and/or neutral radical information of FIG. 2, and may check the output data of FIG. 2.

The network interface 133 may provide access to a network outside the computing system 130. For example, a network may include a plurality of computing systems and communication links, and the communication links may include wired links, optical links, wireless links, or any other types of links.

The memory subsystem 134 may store the program 135_1 or at least a part thereof for a method of modeling damage by incident particles described above with reference to the drawings, and the at least one processor 131 may execute a program (or instructions) stored in the memory subsystem 134 to perform at least some of operations included in the method of modeling damage by incident particles. The memory subsystem 134 may include read only memory (ROM), random access memory (RAM), etc.

The storage 135 is a non-transitory computer-readable storage medium, and stored data may not be lost even when power supplied to the computing system 130 is cut off. For example, the storage 135 may include a non-volatile memory device or a storage medium, such as magnetic tape, an optical disk, or a magnetic disk. Also, the storage 135 may be detachable from the computing system 130. As shown in FIG. 11, the storage 135 may store the program 135_1 and the data 135_2. Before being executed by the at least one processor 131, at least a portion of the program 135_1 may be loaded into the memory subsystem 134. In some implementations, the storage 135 may store a file written in a programing language, and the program 135_1 generated from the file by a compiler or the like or at least a part of the program 135_1 may be loaded to the memory subsystem 134. The data 135_2 may include data needed to perform the plasma process simulation method described above with reference to the drawings, e.g., ion information, material information, and/or neutral radical information of FIG. 2. Also, the data 135_2 may include data generated by performing the plasma process simulation method described above with reference to the drawings, e.g., output data of FIG. 2.

While the disclosure has been particularly shown and described with reference to embodiments thereof, it will be understood that various changes in form and details may be made therein without departing from the spirit and scope of the following claims.

1. A method for simulating a plasma process for a wafer, the method including:
defining a plasma reaction for the wafer;
calculating a reaction parameter of the plasma reaction based on a physical reaction and a chemical reaction that occur at the wafer;
generating a plasma process simulation profile based on the calculated reaction parameter; and
comparing the plasma process simulation profile with an experimental simulation profile to perform a plasma treatment for the wafer.

2. The plasma process simulation method of claim 1, wherein the reaction parameter has at least one of a temperature of the wafer and a temperature of a bottom electrode supporting the wafer.

3. The plasma process simulation method of claim 1, wherein the reaction parameter has information of a material included in the wafer and information of plasma.

4. The plasma process simulation method of claim 1, wherein calculating the reaction parameter comprises:
obtaining at least one of ion information of the plasma, information of the wafer, and neutral radical information;
calculating a first parameter regarding the physical reaction; and
calculating a second parameter regarding the chemical reaction.

5. The plasma process simulation method of claim 4, wherein the plasma ion information comprises at least one of an average atomic mass of plasma ions, an average atomic number of the plasma ions, an energy of the plasma ions, and an angle of incidence of the plasma ions, and
wherein the wafer information comprises at least one of an average atomic mass of materials constituting the wafer or an average atomic number of the materials constituting the wafer.

6. The plasma process simulation method of claim 4, wherein calculating the first parameter comprises:
calculating a cohesive energy;
calculating a threshold energy based on the cohesive energy;
calculating a maximum angle of incidence of plasma ions based on the cohesive energy and the threshold energy; and
calculating a sputtering yield based on the cohesive energy and the threshold energy.

7. The plasma process simulation method of claim 4, wherein calculating the second parameter comprises:
calculating adsorption energy; and
calculating a sticking coefficient based on the adsorption energy.

8. The plasma process simulation method of claim 7, wherein the sticking coefficient has at least one of a temperature of the wafer and a temperature of a bottom electrode supporting the wafer.

9. A plasma process simulation method comprising:
defining a plasma reaction for a wafer;
calculating a reaction parameter of the plasma reaction;
generating, based on the calculated reaction parameter, a calculated simulation profile of a plasma process; and
generating a final simulation profile based on the calculated simulation profile to perform a plasma treatment for the wafer,
wherein the reaction parameter is calculated based on a physical sputtering reaction and a chemical adsorption reaction that occur at the wafer.

10. The plasma process simulation method of claim 9, wherein generating the final simulation profile comprises:
comparing an experimental simulation profile with the calculated simulation profile.

11. The plasma process simulation method of claim 10, further comprising:
based on a difference between the calculated simulation profile and the experimental simulation profile being outside an error range, correcting the reaction parameter.

12. The plasma process simulation method of claim 10, wherein, based on a difference between the calculated simulation profile and the experimental simulation profile being within an error range, the calculated simulation profile is selected as the final simulation profile.

13. The plasma process simulation method of claim 9, wherein generating the final simulation profile comprises:
based on no existence of experimental simulation profile, selecting the calculated simulation profile as the final simulation profile.

14. The plasma process simulation method of claim 9, wherein the reaction parameter has an average atomic mass of materials constituting the wafer, an average atomic number of the materials constituting the wafer, an average atomic mass of plasma ions, an average atomic number of the plasma ions, and a temperature of the wafer as variables.

15. The plasma process simulation method of claim 9, wherein calculating the reaction parameter comprises:
calculating parameters of the physical sputtering reaction based on threshold energy, and wherein the threshold energy is calculated based on:
$${E}_{th} - \{ \begin{matrix}6.7 \frac{{E}_{coh}}{γ} , & {M}_{1} > {M}_{2} \\ ( 1 + 5.7 \frac{{M}_{1}}{{M}_{2}} ) \frac{{E}_{coh}}{γ} , & {M}_{1} \leq {M}_{2}\end{matrix}$$
$$γ = \frac{4 {M}_{1} {M}_{2}}{{( {M}_{1} + {M}_{2} )}^{2}}$$
where Eₜₕ denotes the threshold energy, E_{coh} denotes cohesive energy, M₁ denotes an average atomic mass of plasma ions, and M₂ denotes an average atomic mass of the wafer.

16. The plasma process simulation method of claim 9, wherein calculating the reaction parameter comprises:
calculating parameters of the physical sputtering reaction based on a sputtering yield; and
calculating a maximum angle of incidence of plasma ions, at which the sputtering yield is maximized, based on:
$${θ}_{max} = \frac{π}{2} - 286 {ψ}^{0.45} , ψ = {n}^{0.5} {a}^{3 / 2} \frac{{( {Z}_{1} {Z}_{2} )}^{0.5}}{{( {Z}_{1}^{2 / 3} + {Z}_{2}^{2 / 3} )}^{0.25}} {( E )}^{- 0.5} , a = 0. 4685 {( \frac{1}{{Z}_{1}^{2 / 3} + {Z}_{2}^{2 / 3}} )}^{0.5}$$
wherein the sputtering yield is calculated based on:
$$Y ( E , θ ) = Y ( E , 0 ) [ {cos ( θ )}^{- f} exp \{ f cos ( {θ}_{max} ) [ 1 - \frac{1}{cos ( θ )} ] \}$$
$$f = ( 1 + 2.5 \frac{1 - ζ}{ζ} ) {f}_{s} \qquad {f}_{s} = ( 0.94 - 0.00133 \frac{{M}_{2}}{{M}_{1}} ) {E}_{c o h}^{0.5} \qquad ζ = 1 - {( \frac{{E}_{th}}{E} )}^{0.5}$$
where θ denotes the angle of incidence of the plasma ions, θₘₐₓ denotes an angle of incidence at which the sputtering yield is maximized, Y denotes the sputtering yield, Eₜₕ denotes threshold energy, E denotes incident plasma ion energy, E_{coh} denotes cohesive energy, M₁ denotes an average atomic mass of the plasma ions, M₂ denotes an average atomic mass of the wafer, Z₁ denotes an average atomic number of the plasma ions, Z₂ denotes an average atomic number of the wafer, and n denotes a number density of the wafer.

17. The plasma process simulation method of claim 9, wherein calculating the reaction parameter comprises:
calculating parameters of the chemical adsorption reaction based on a sticking coefficient, and
wherein the sticking coefficient is calculated based on:
$$SC ( T ) = \frac{{P}_{trap}}{1 + exp ( - \frac{{E}_{b}}{{k}_{B} T} )} \\ {P}_{trap} = {\int }_{0}^{{E}_{b}} 2 {( \frac{E}{π} )}^{\frac{1}{2}} {( \frac{1}{{k}_{B} T} )}^{\frac{3}{2}} exp ( - \frac{E}{{k}_{B} T} ) d E$$
where T denotes a temperature of a surface of the wafer, SC(T) denotes the sticking coefficient according to the temperature, E_{b} denotes adsorption energy, Pₜᵣₐₚ denotes a Maxwell-Boltzmann distribution of the adsorption energy, and kB denotes Boltzmann constant.

18. A method of manufacturing a semiconductor device, the method comprising:
preparing a wafer by placing the wafer on a bottom electrode;
defining a plasma reaction for the wafer;
calculating a reaction parameter of the plasma reaction;
generating, based on the calculated reaction parameter, a calculated simulation profile of a plasma process;
generating a final simulation profile based on the calculated simulation profile;
performing a plasma treatment for the wafer based on the final simulation profile; and
performing, based on the plasma treatment being performed, semiconductor processes on the wafer,
wherein the reaction parameter include information of a material included in the wafer, information of plasma, and a temperature of the wafer.

19. The method of claim 18, wherein generating the final simulation profile comprises:
comparing an experimental simulation profile with the calculated simulation profile; and
correcting the reaction parameter based on a difference between the calculated simulation profile and the experimental simulation profile being outside an error range.

20. The method of claim 18, wherein the plasma process simulation profile has a temperature of the wafer, an angle of incidence of plasma ions with respect to the wafer, and an incident energy of the plasma ions as variables.

21.-24. (canceled)
